(19) United States
(12) Patent Application Publication
(10) Pub. No.: US 2016/0111295 A1
(43) Pub. Date: Apr. 21, 2016

(54) METHOD FOR FABRICATING SEMICONDUCTOR DEVICE

(71) Applicant: Powerchip Technology Corporation, Hsinchu (TW)

(72) Inventors: Kai-Yao Shih, Hsinchu City (TW); Ssu-Ting Wang, Taichung City (TW); Te-Yuan Yin, Hsinchu City (TW); Po-Cheng Chang, Hsinchu County (TW); Hsin Tai, Hsinchu City (TW)

(21) Appl. No.: 14/566,721

(22) Filed: Dec. 11, 2014

(30) Foreign Application Priority Data
Oct. 15, 2014 (TW) 103135650

(51) Int. Cl. H01L 21/311; H01L 21/308

(52) U.S. Cl. CPC H01L 21/31111; H01L 21/3086

(57) ABSTRACT

A method for fabricating a semiconductor device is provided. The method includes the following steps. A substrate including a memory cell region and a peripheral region is provided, and a plurality of isolation structures are formed in the substrate. Each of the isolation structures contains an exposed portion protruding beyond the surface of the substrate. A first dielectric layer is formed on the substrate. A protective layer is formed on a sidewall of the exposed portion of each of the isolation structures. The first dielectric layer on the peripheral region is removed. A second dielectric layer is formed on the substrate of the peripheral region.

### CROSS-REFERENCE TO RELATED APPLICATION

This application claims the priority benefit of Taiwan application serial no. 103135650, filed on Oct. 15, 2014. The entirety of the above-mentioned patent application is hereby incorporated by reference herein and made a part of this specification.

### BACKGROUND OF THE INVENTION

1. Field of the Invention

The invention relates to a method for fabricating a semiconductor device.

2. Description of Related Art

As the size of the semiconductor device continues to be smaller, the integration of different devices on the same chip has become the trend in the design and the fabrication of a product. Using a non-volatile memory as example, a memory cell, a low-voltage device, a high-voltage device, or a capacitor . . . etc. are, for instance, included on the same chip at the same time. The devices in the substrate are, for instance, isolated by shallow-trench isolation (STI) structures, and respectively include a gate and a gate oxide layer. Since the needed operation voltage and the efficacy of different devices are different, the thicknesses of the gate oxide layers are also different.

In general, a method for fabricating gate oxide layers having different thicknesses includes disposing isolation structures in the substrate to define active areas, and then forming gate oxide layers having different thicknesses in different active areas. However, in the fabrication process, when gate oxide layers having other thicknesses are removed, a divot is formed in the peripheral portion of a top corner of the active areas. Moreover, as the number of times the gate oxide layers are removed is increased, the generated divot region also becomes larger. For instance, the divot region of a low-voltage device region is often greater than the divot region of a high-voltage device region. Since the thickness of the gate oxide layer of the divot region is smaller, the gate oxide layer readily becomes the path of leakage current of the device. As a result, electrical issues such as breakdown voltage or starting voltage are generated, such that the reliability of the device is reduced.

Therefore, how to solve the issue of the generation of a divot in the periphery of a top corner of the active areas when gate oxide layers having different thicknesses are fabricated, so as to prevent the generation of leakage current of a device and thereby increase the reliability of the device, is a current topic that needs to be researched.

### SUMMARY OF THE INVENTION

The invention provides a method for fabricating a semiconductor device. The method can alleviate the issue of the generation of a divot in the periphery of a top corner of an active area so as to prevent the generation of leakage current of a device, and thereby increase the reliability of the device.

The invention provides a method for fabricating a semiconductor device including the following steps. A substrate is provided. The substrate includes a memory cell region and a peripheral region, and a plurality of isolation structures are formed in the substrate. Each of the isolation structures contains an exposed portion protruding beyond the surface of the substrate. A first dielectric layer is formed on the substrate. A protective layer is formed on a sidewall of the exposed portion of each of the isolation structures. The first dielectric layer on the peripheral region is removed. A second dielectric layer is formed on the substrate of the peripheral region.

In an embodiment of the invention, the protective layer is formed by the following steps. A material layer is formed on the substrate to cover the first dielectric layer and the isolation structures. The material layer covering the first dielectric layer and a portion of the isolation structures is removed to form a protective layer on a sidewall of the exposed portion of each of the isolation structures.

In an embodiment of the invention, the material layer is formed by performing an etch-back process.

In an embodiment of the invention, the protective layer is formed by performing a chemical vapor deposition process.

In an embodiment of the invention, the material of the protective layer includes α-Si, SiO₂, SiN, or a combination thereof.

In an embodiment of the invention, the thickness of the protective layer is between 3 nm and 10 nm.

In an embodiment of the invention, the thickness of the protective layer after the second dielectric layer is formed is greater than the thickness of the protective layer before the second dielectric layer is formed.

In an embodiment of the invention, the first dielectric layer is removed by performing a wet etching process.

In an embodiment of the invention, the peripheral region includes a first region and a second region. Moreover, after the step in which the second dielectric layer is formed on the substrate of the peripheral region, the following steps are included. The second dielectric layer on the second region is removed. A third dielectric layer is formed on the substrate of the second region, wherein the thickness of the third dielectric layer is less than the thickness of the second dielectric layer.

In an embodiment of the invention, the second dielectric layer is removed by performing a wet etching process.

In an embodiment of the invention, the peripheral region further includes a third region. Moreover, after the step in which the third dielectric layer is formed on the substrate of the second region, a step in which a fourth dielectric layer is formed on the substrate of the third region is further included.

In an embodiment of the invention, the thickness of the fourth dielectric layer is less than the thickness of the third dielectric layer.

In an embodiment of the invention, the thickness of the fourth dielectric layer is less than the thickness of the third dielectric layer.

In an embodiment of the invention, the first region is a medium-voltage device region, and the second region and the third region are low-voltage device regions.

In an embodiment of the invention, the second region is used to form an input/output transistor, and the third region is used to form a core transistor.

In an embodiment of the invention, the isolation structures are formed by the following steps. A liner layer and a mask layer are formed on a substrate. The mask layer, the liner layer, and the substrate are patterned to form a plurality of trenches in the substrate. An insulation material layer is filled in the trenches. The liner layer and the mask layer are removed to form the isolation structures.

In an embodiment of the invention, the thickness of the second dielectric layer is between 150 angstroms and 200 angstroms.

Based on the above, in the method for fabricating a semiconductor device of the invention, by disposing a protective layer on a sidewall of an isolation structure, the protective layer can prevent the isolation structure adjacent to the periphery of a top corner of an active area from being removed when a dielectric layer on the active area is removed, thereby preventing the generation of a divot in the periphery of a top corner of the active area. Moreover, since the protective layer is located on a sidewall of the isolation structure protruding beyond the surface of the substrate, side etching to the isolation structure caused by an etchant can be prevented, and therefore the generation of a divot in the periphery of a top corner of the active area is prevented. As a result, electrical issues such as leakage current of a device are prevented, and the reliability of the device is thus increased.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1K are cross-sectional schematics of a fabrication process of a semiconductor device illustrated according to an embodiment of the invention.

### DESCRIPTION OF THE EMBODIMENTS

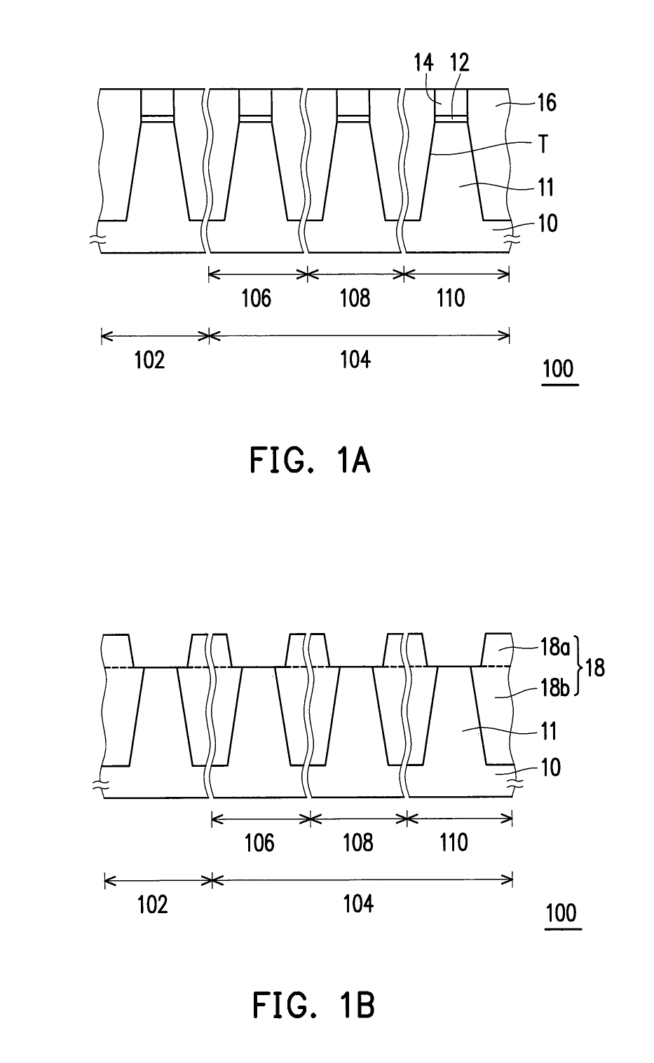

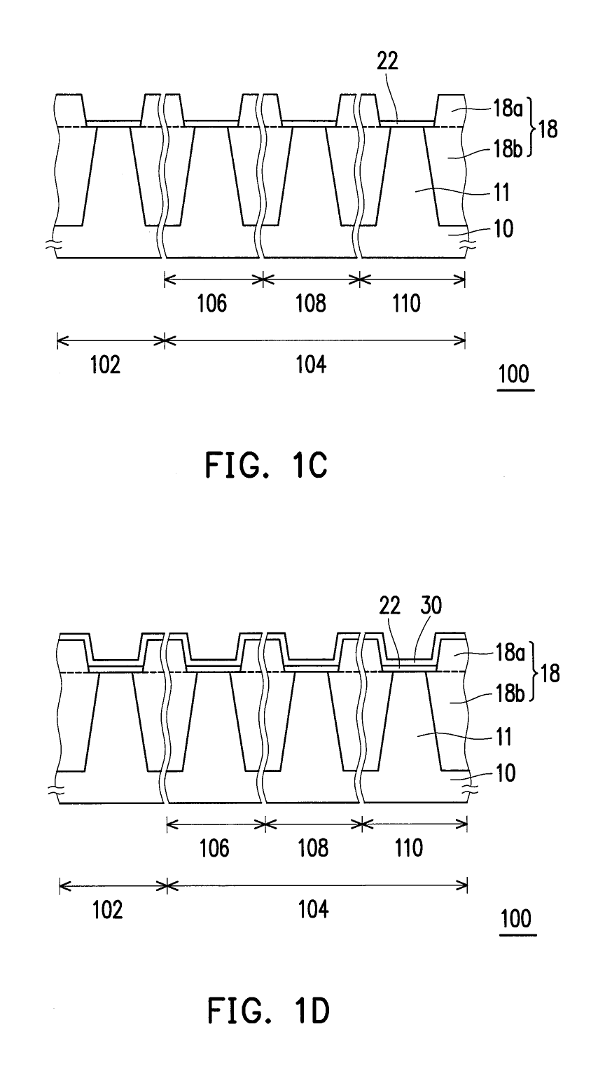

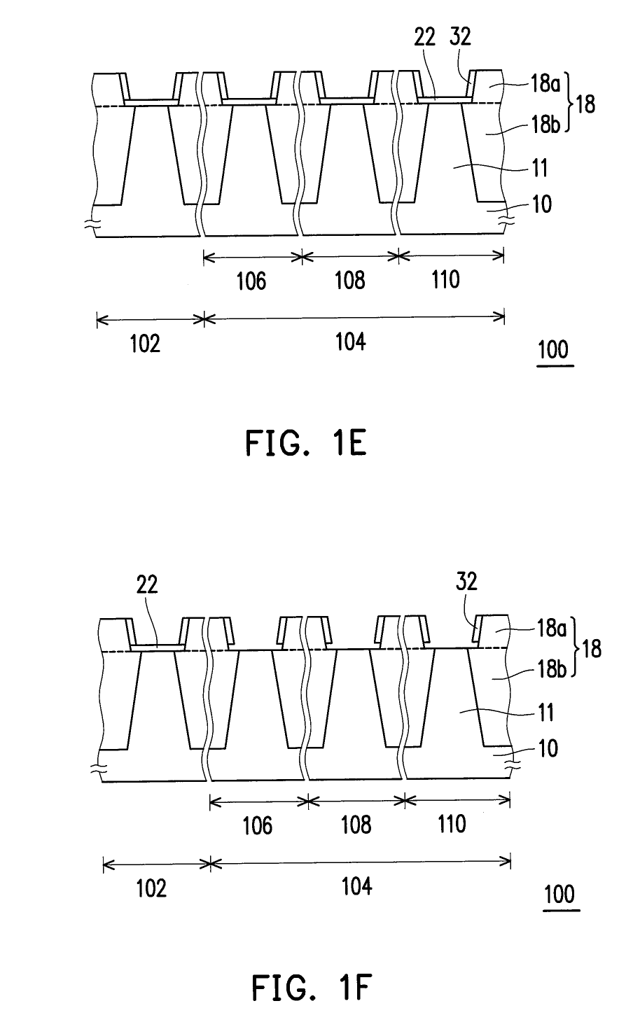

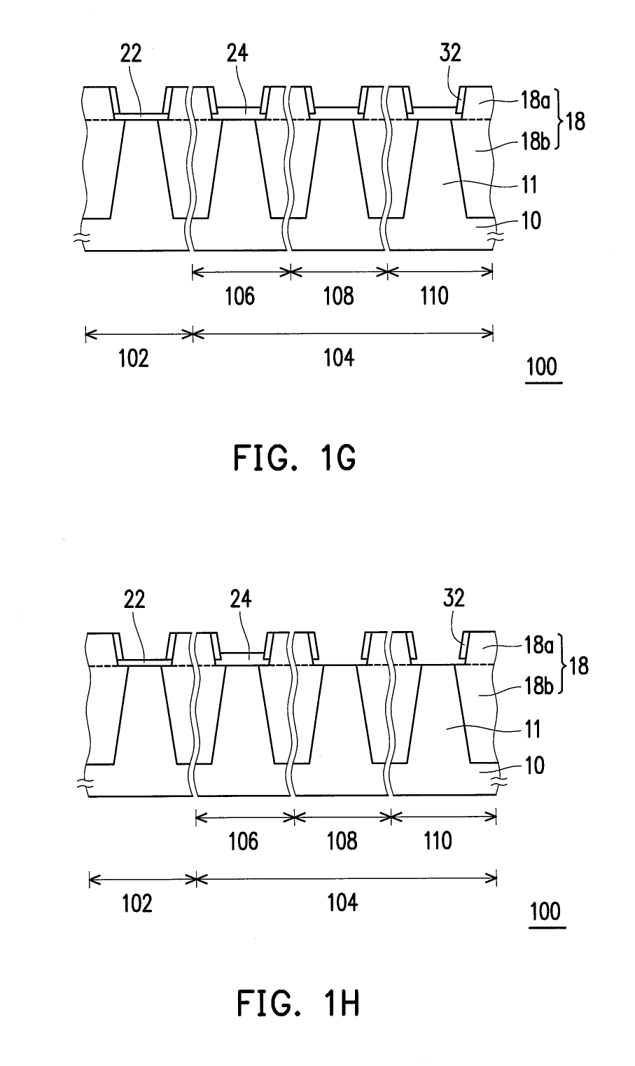

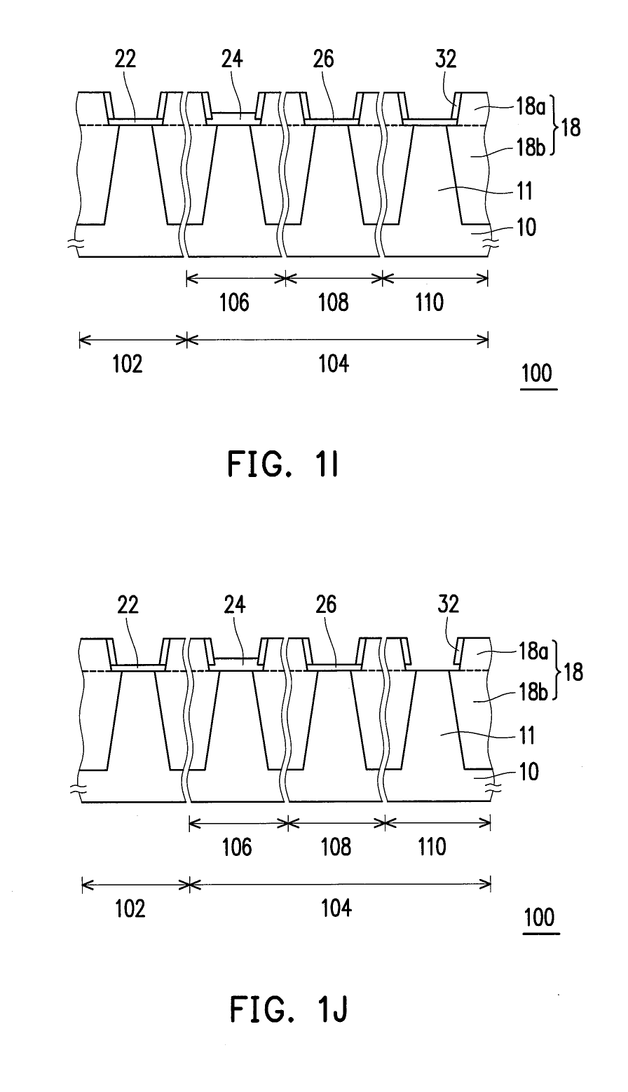

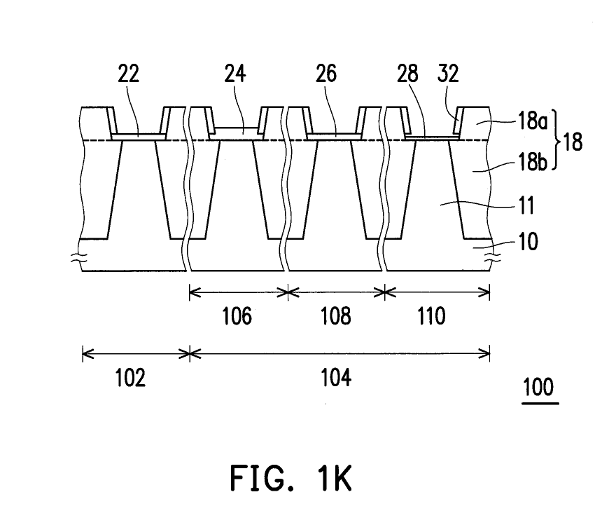

FIG. 1A to FIG. 1K are cross-sectional schematics of a fabrication process of a semiconductor device 100 illustrated according to an embodiment of the invention.

Referring to FIG. 1A, a substrate 10 is provided. The material of the substrate 10 includes a semiconductor, a semiconductor compound, or a silicon-on-insulator (SOI). The substrate 10 is, for instance, a silicon substrate. The substrate 10 includes a memory cell region 102 and a peripheral region 104. The peripheral region 104 includes, for instance, a peripheral circuit region other than a memory cell. The peripheral region 104 can include a first region 106, a second region 108, and a third region 110. In an embodiment, the first region 106 is, for instance, a medium-voltage device region; and the second region 108 and the third region 110 are, for instance, low-voltage device regions, but the invention is not limited thereto. In other embodiments, the first region 106, the second region 108, and the third region 110 can each form the needed device such as a transistor or a capacitor. For instance, the second region 108 is, for instance, used to form an input/output transistor, and the third region 110 is, for instance, used to form a core transistor.

Then, a liner layer 12 is formed on the substrate 10. The material of the liner layer 12 is, for instance, silicon oxide. The liner layer 12 is formed by performing, for instance, a thermal oxidation process. Then, a mask layer 14 is formed on the liner layer 12. The material of the mask layer 14 is, for instance, an insulation material such as silicon nitride, silicon carbide, or silicon carbon nitride. The mask layer 14 is formed by performing, for instance, a chemical vapor deposition process. Then, the mask layer 14, the liner layer 12, and the substrate 10 are patterned to form a plurality of trenches T in the substrate 10. The patterning method includes, for instance, lithography and etching techniques. Then, an insulation material layer 16 is filled in the trenches T. The material of the insulation material layer 16 is, for instance, silicon oxide. Then, using the patterned mask layer 14 as an etch-stop layer, a chemical mechanical polishing process is performed on the substrate 10 to remove the insulation material layer 16 outside the trenches T.

Referring to FIG. 1B, the patterned mask layer 14 and the patterned liner layer 12 are removed to form a plurality of isolation structures 18 and a plurality of active areas 11 in the substrate 10. The patterned mask layer 14 and the patterned liner layer 12 are removed by performing a wet etching process. In an embodiment, the memory cell region 102, the first region 106, the second region 108, and the third region 110 are, for instance, isolated from one another via the isolation structures 18. Moreover, each of the regions can include a plurality of isolation structures 18. The isolation structures 18 protrude beyond the surface of the substrate 10. In other words, the top surface of the isolation structures 18 is higher than the top surface of the substrate 10. Each of the isolation structures 18 contains an exposed portion 18a protruding beyond the surface of the substrate 10 and a bottom portion 18b located in the substrate 10 and completely filling the trenches T.

Referring to FIG. 1C, a first dielectric layer 22 is formed on the substrate 10 of the memory cell region 102 and the peripheral region 104. The material of the first dielectric layer 22 is, for instance, silicon oxide, and the first dielectric layer 22 is formed by performing, for instance, a thermal oxidation process. The thickness of the first dielectric layer 22 is, for instance, between 60 angstroms and 100 angstroms. In an embodiment, the thickness of the first dielectric layer 22 is, for instance, 80 angstroms. The first dielectric layer 22 of the memory cell region 102 is, for instance, used as a tunneling dielectric layer of a memory cell.

Referring to FIG. 1D, a material layer 30 is formed on the substrate 10 to cover the first dielectric layer 22 and the isolation structures 18. The material of the material layer 30 includes α-Si, SiO₂, SiN, or a combination thereof. The material layer 30 is formed by performing a chemical vapor deposition process. In an embodiment, the material layer 30 is formed by performing, for instance, a low-pressure chemical vapor deposition (LPCVD) process. The thickness of the material layer 30 is, for instance, between 10 nm and 15 nm.

Referring to FIG. 1E, an anisotropic etching process is performed on the substrate 10 to remove the material layer 30 covering the first dielectric layer 22 and a portion of the isolation structures 18, so as to form a protective layer 32 on a sidewall of the exposed portion 18a of each of the isolation structures 18. A step of removing the material layer 30 includes, for instance, removing the material layer 30 on the top surface of the exposed portion 18a via an etch-back process. The thickness of the protective layer 32 is, for instance, between 3 nm and 10 nm. In an embodiment, the thickness of the protective layer 32 is, for instance, less than or equal to half of the thickness of the material layer 30. For instance, the thickness of the material layer 30 is, for instance, 10 nm, and the thickness of the protective layer 32 formed after the etch-back is, for instance, 3 nm.

Referring to FIG. 1F, the first dielectric layer 22 on the peripheral region 104 is removed to expose a portion of the substrate 10. The first dielectric layer 22 is removed by performing a wet etching process, and the used etchant is, for instance, dilute HF (DHF). In an embodiment, before the above step is performed, a step in which a patterned photoresist layer (not shown) is formed is further included to cover the first dielectric layer 22 of the memory cell region 102. Alternately, a conductor layer (not shown) is formed on the first dielectric layer 22 of the memory cell region 102 as a floating gate of a memory cell.

Referring to FIG. 1G, a second dielectric layer 24 is formed on the substrate 10 of the peripheral region 104. The material of the second dielectric layer 24 is, for instance, silicon oxide, and the second dielectric layer 24 is formed by performing, for instance, a thermal oxidation process. The thickness of the second dielectric layer 24 is, for instance, between 150 angstroms and 200 angstroms. The second dielectric layer 24 of the first region 106 is, for instance, used as a gate dielectric layer of a medium-voltage device. In an embodiment, the thickness of the second dielectric layer 24 is, for instance, greater than the thickness of the first dielectric layer 22.

The method for forming the protective layer 32 is exemplary and is not intended to limit the invention. In another embodiment, when the second dielectric layer 24 is formed, the thickness of the protective layer 32 is also increased due to high-temperature oxidation, and the protective layer 32 is completely oxidized to form a dielectric layer. In this way, the thickness of the protective layer 32 after the second dielectric layer 24 is formed is greater than the thickness of the protective layer 32 before the second dielectric layer 24 is formed. For instance, the thickness of the protective layer 32 after the second dielectric layer 24 is formed is 1.3 times to 1.5 times the thickness of the protective layer 32 before the second dielectric layer 24 is formed.

Referring to FIG. 1H, the second dielectric layer 24 on the second region 108 and the third region 110 of the peripheral region 104 is removed to expose a portion of the substrate 10. The second dielectric layer 24 is removed by performing a wet etching process, and the used etchant is, for instance, DHF. In an embodiment, before the above step is performed, a step in which a patterned photoresist layer (not shown) is formed is further included to cover the first dielectric layer 22 of the memory cell region 102 and the second dielectric layer 24 of the first region 106.

It should be mentioned that, since each of the isolation structures 18 has a protective layer 32, when the second dielectric layer 24 is removed, the protective layer 32 can prevent a portion of the isolation structures 18 adjacent to the surface of the substrate 10 from being removed together. Moreover, since the protective layer 32 is located on a sidewall of the exposed portion 18a of the isolation structures 18, the phenomenon of side etching to the isolation structures 18 caused by the etchant can further be prevented, and therefore the generation of a divot in the periphery of a top corner of the active area 11 is prevented.

Referring to FIG. 1I, a third dielectric layer 26 is formed on the substrate 10 of the second region 108 and the third region 110 of the peripheral region 104. The material of the third dielectric layer 26 is, for instance, silicon oxide, and the third dielectric layer 26 is formed by performing, for instance, a thermal oxidation process. The thickness of the third dielectric layer 26 is, for instance, between 40 angstroms and 60 angstroms. In an embodiment, the thickness of the third dielectric layer 26 is, for instance, 50 angstroms. In an embodiment, the thickness of the third dielectric layer 26 is, for instance, less than the thickness of the second dielectric layer 24.

A method for fabricating the semiconductor device 100 includes forming three dielectric layers having different thicknesses, that is, the first dielectric layer 22, the second dielectric layer 24, and the third dielectric layer 26. However, the number is exemplary, and is not intended to limit the invention. In other embodiments of the invention, the method for fabricating the semiconductor device 100 can include forming two, four, or a plurality of dielectric layers having different thicknesses. For instance, the method for fabricating the semiconductor device 100 can further include forming a fourth dielectric layer 28 as described in the following steps.

Referring to FIG. 1J, the third dielectric layer 26 on the third region 110 of the peripheral region 104 is removed to expose a portion of the substrate 10. The third dielectric layer 26 is removed by performing a wet etching process, and the used etchant is, for instance, DHF. In an embodiment, before the above step is performed, a step in which a patterned photoresist layer (not shown) is formed is further included to cover the first dielectric layer 22 of the memory cell region 102, the second dielectric layer 24 of the first region 106, and the third dielectric layer 26 of the second region 108.

It should be mentioned that, since each of the isolation structures 18 has a protective layer 32, when the first dielectric layer 22, the second dielectric layer 24, and the third dielectric layer 26 are removed from the active area 11 of the third region 110 of the peripheral region 104, the removal of the isolation structures 18 adjacent to the periphery of a top corner of the active area 11 at the same time can be prevented, and therefore the generation of a divot is prevented. In other words, the protective layer 32 can prevent the generation of a large divot region as the number of times that different dielectric layers in the periphery of a top corner of the active area 11 are removed is increased, and therefore the generation of electrical issues of the device is prevented.

Referring to FIG. 1K, a fourth dielectric layer 28 is formed on the substrate 10 of the third region 110 of the peripheral region 104. The material of the fourth dielectric layer 28 is, for instance, silicon oxide, and the fourth dielectric layer 28 is formed by performing, for instance, a chemical vapor deposition process or a thermal oxidation process. The thickness of the fourth dielectric layer 28 is, for instance, between 15 angstroms and 25 angstroms. In an embodiment, the thickness of the third dielectric layer 26 is, for instance, 20 angstroms. In an embodiment, the thickness of the fourth dielectric layer 28 is, for instance, less than the thickness of the third dielectric layer 26 and the thickness of the second dielectric layer 24.

A subsequent process for fabricating the semiconductor device 100 includes forming a conductor layer (not shown) on the substrate 10, and after patterning, respectively forming different gate structures on the memory cell region 102 and the peripheral region 104, and thereby respectively forming a needed device such as a memory cell, a select transistor, or a capacitor on the memory cell region 102, the first region 106, the second region 108, and the third region 110. The subsequent process for completing the devices of each of the regions should be known to those skilled in the art, and is not repeated herein.

In the method for fabricating a semiconductor device of the invention, after a tunneling dielectric layer (such as the first dielectric layer 22) of the memory cell is formed and before a thickest gate dielectric layer (such as the second dielectric layer 24) in the peripheral circuit region is formed, by disposing a protective layer on a sidewall of an isolation structure, a divot of the isolation structure formed in the periphery of a top corner of an active area caused by the subsequent repeated removal of gate dielectric layers (gate dielectric layer of a medium-voltage device, gate dielectric layer of an input/output transistor, or gate dielectric layer of a core transistor) of the peripheral circuit region can be prevented. As a result, leakage current of a device can be prevented, and therefore the reliability of the device is increased.

Based on the above, in the method for fabricating a semiconductor device of the invention, by disposing a protective layer on a sidewall of an isolation structure, the protective layer can prevent the isolation structure adjacent to the periphery of a top corner of an active area from being removed when a dielectric layer on the active area is removed, and therefore the generation of a divot in the periphery of a top corner of the active area is prevented. Moreover, when the number of times that dielectric layers on the same active area are removed is increased, the protective layer can also prevent the generation of a large divot region. Moreover, since the protective layer is located on a sidewall of the isolation structure protruding beyond the surface of the substrate, side etching to the isolation structure caused by an etchant can be prevented, and therefore the generation of a divot in the periphery of a top corner of the active area is prevented. As a result, electrical issues such as leakage current of a device are prevented, and therefore the reliability of the device is increased.

Although the invention has been described with reference to the above embodiments, it will be apparent to one of the ordinary skill in the art that modifications to the described embodiments may be made without departing from the spirit of the invention. Accordingly, the scope of the invention is defined by the attached claims not by the above detailed descriptions.

What is claimed is:

1. A method for fabricating a semiconductor device, comprising:
providing a substrate, the substrate comprising a memory cell region and a peripheral region, wherein a plurality of isolation structures are formed in the substrate, and each of the isolation structures contains an exposed portion protruding beyond a surface of the substrate;
forming a first dielectric layer on the substrate;
forming a protective layer on a sidewall of the exposed portion of each of the isolation structures;
removing the first dielectric layer on the peripheral region; and
forming a second dielectric layer on the substrate of the peripheral region.

2. The method of claim 1, wherein a step of forming the protective layer comprises:
forming a material layer on the substrate, wherein the material layer covers the first dielectric layer and the isolation structures; and
removing the material layer covering the first dielectric layer and a portion of the isolation structures so as to form the protective layer on a sidewall of the exposed portion of each of the isolation structures.

3. The method of claim 2, wherein a step of removing the material layer comprises performing an etch-back process.

4. The method of claim 1, wherein a step of forming the protective layer comprises performing a chemical vapor deposition process.

5. The method of claim 1, wherein a material of the protective layer is selected form a group consisting of α-Si, SiO₂, SiN, and a combination thereof.

6. The method of claim 1, wherein a thickness of the protective layer is between 3 nm and 10 nm.

7. The method of claim 1, wherein a thickness of the protective layer after the second dielectric layer is formed is greater than a thickness of the protective layer before the second dielectric layer is formed.

8. The method of claim 1, wherein a step of removing the first dielectric layer comprises performing a wet etching process.

9. The method of claim 1, wherein the peripheral region comprises a first region and a second region, and further comprising, after the step in which the second dielectric layer is formed on the substrate of the peripheral region:
removing the second dielectric layer on the second region; and
forming a third dielectric layer on the substrate of the second region, wherein a thickness of the third dielectric layer is less than a thickness of the second dielectric layer.

10. The method of claim 9, wherein a step of removing the second dielectric layer comprises performing a wet etching process.

11. The method of claim 9, wherein the peripheral region further comprises a third region, and further comprising, after the step in which the third dielectric layer is formed on the substrate of the second region, forming a fourth dielectric layer on the substrate of the third region.

12. The method of claim 11, wherein a thickness of the fourth dielectric layer is less than a thickness of the third dielectric layer.

13. The method of claim 11, wherein the first region is a medium-voltage device region, and the second region and the third region are low-voltage device regions.

14. The method of claim 13, wherein the second region is used to form an input/output transistor, and the third region is used to form a core transistor.

15. The method of claim 1, wherein a step of forming the plurality of isolation structures comprises:
forming a liner layer and a mask layer on the substrate;
patterning the mask layer, the liner layer, and the substrate to form a plurality of trenches in the substrate;
filling an insulation material layer in the trenches; and
removing the liner layer and the mask layer to form the isolation structures.

16. The method of claim 1, wherein a thickness of the second dielectric layer is between 150 angstroms and 200 angstroms.
